(19) United States
(12) Patent Application Publication
(10) Pub. No.: US 2022/0373580 A1
(43) Pub. Date: Nov. 24, 2022

(54) Measurement Device, Measurement Method, and Storage Medium

(71) Applicant: HIOKI E.E. CORPORATION, Ueda-shi (JP)

(72) Inventors: Hiroki KOBAYASHI, Ueda-shi (JP); Shinya Takiguchi, Ueda-shi (JP)

(73) Assignee: HIOKI E.E. CORPORATION, Ueda-shi (JP)

(21) Appl. No.: 17/663,786

(22) Filed: May 17, 2022

(30) Foreign Application Priority Data
May 18, 2021 (JP) 2021-084021

(51) Int. Cl. G01R 21/133; G01R 19/14

(52) U.S. Cl. CPC G01R 21/133; G01R 19/14; H02J 2207/20; H02J 7/0063

(57) ABSTRACT

A measurement device configured to measure a state of a target device that is capable of switching at least one transmission direction of a channel among transmission directions of electric power transmitted through a plurality of channels. The measurement device retains information indicating whether a reference transmission direction of the electric power transmitted to each of the channels is an input direction in which the electric power is input to the target device or an output direction in which the electric power is output from the target device, acquires a signal indicating a direction and intensity of the electric power, and computes at least one of an input electric power and an output electric power of the target device on the basis of the sign indicating the direction of the above-described signal with respect to the reference transmission direction of the electric power of each of the channels.

### CROSS-REFERENCE TO RELATED APPLICATION

The present application claims priority 35 U.S.C. § 119 to Japanese Patent Publication No. JP 2021-084021 (filed on May 18, 2021) which is hereby incorporated by reference in its entirety.

### TECHNICAL FIELD

The present invention relates to a measurement device, a measurement method, and a storage medium.

### BACKGROUND ART

JP6372608B2 discloses an electric power transmission system that obtains efficiency via a communication circuit unit after transmission of electric power from a power transmitter to a power receiver has been started.

### SUMMARY OF INVENTION

With the system described above, it is possible to measure a transmission state of the electric power transmitted from the power transmitter to the power receiver by obtaining the electric power efficiency.

However, target devices that can transmit the electric power and that are targets of the measurement include devices in which the transmission direction of the electric power that is transmitted through transmission line is switched in accordance with operation modes (operation states) that define how the electric power is to be transmitted. In such target devices, computation formulae for computing indices indicating the transmission state are required for all of transmission patterns that can be assumed, and there may be a case in which the transmission states of all transmission patterns need to be obtained in a successive manner by using all of the computation formulae.

In such a case, for example, for every time periods during which the respective operation modes of the target devices are executed, a measurer needs to select, from all computation results, a result of a suitable computation formula applicable to the operation mode of the target device executed during the time period. Therefore, there is a problem in that a result of a computation formula different from the suitable computation formula is erroneously selected due to a human error caused by the measurer.

The present invention has been conceived in light of the above-described problem, and an object thereof is to appropriately measure a state of a target device in accordance with an operation mode.

According to an aspect of the present invention, a measurement device measures a state of a target device, the target device being capable of switching at least one transmission direction of a channel among transmission directions of electric power transmitted through a plurality of channels. This measurement device is provided with: a reference retaining circuit configured to retain information indicating whether a reference transmission direction of the electric power transmitted through each of the channel is an input direction in which the electric power is input to the target device or an output direction in which the electric power is output from the target device; and an electric power signal acquisition circuit configured to acquire a signal indicating a direction and intensity of the electric power transmitted through each of the channels. Furthermore, the measurement device is provided with a processor configured to compute at least one of input electric power and output electric power for the target device on the basis of the sign indicating the direction of the signal with respect to the reference transmission direction of the electric power of each of the channels indicated by the information.

According to this aspect, by taking the sign of the signal with respect to the reference transmission direction of the electric power of each of the channels indicated by the information into consideration, it is possible to determine whether the electric power of each of the channels for the target device is the input electric power or the output electric power.

Thus, when the sign of the signal of a specific channel is switched due to switching of the operation mode of the target device, it is possible to suitably determine which of the input electric power and the output electric power the electric power of the specific channel corresponds to. Therefore, the measurement device can appropriately measure the state of the target device in accordance with the operation mode of the target device.

### BRIEF DESCRIPTION OF DRAWINGS

FIG. 1 is a diagram showing a configuration of an electric power transmission system provided with a measurement device in an embodiment of the present invention.

FIG. 2 is a block diagram showing a functional configuration of the measurement device in this embodiment.

FIG. 3 is a diagram for explaining procedures for setting a reference transmission direction of electric power of each channel for a target device that is a target of measurement.

FIG. 4 is a conceptual diagram for explaining a type of reference information indicating the reference transmission direction of the electric power of each channel.

FIG. 5 is a block diagram showing an example of a functional configuration of a processing unit of the measurement device.

FIG. 6 is a diagram for explaining procedures for computing transmission indices corresponding to respective operation modes of the target device in the processing unit.

FIG. 7 is a flowchart showing a measurement method of electric power efficiency in this embodiment.

FIG. 8 is a flowchart showing a measurement method of electric power loss in this embodiment.

FIG. 9 is a diagram for explaining a shift of a displayed image along with switching of the operation mode of the target device.

### DESCRIPTION OF EMBODIMENTS

An embodiment of the present invention will be described below with reference to the attached drawings.

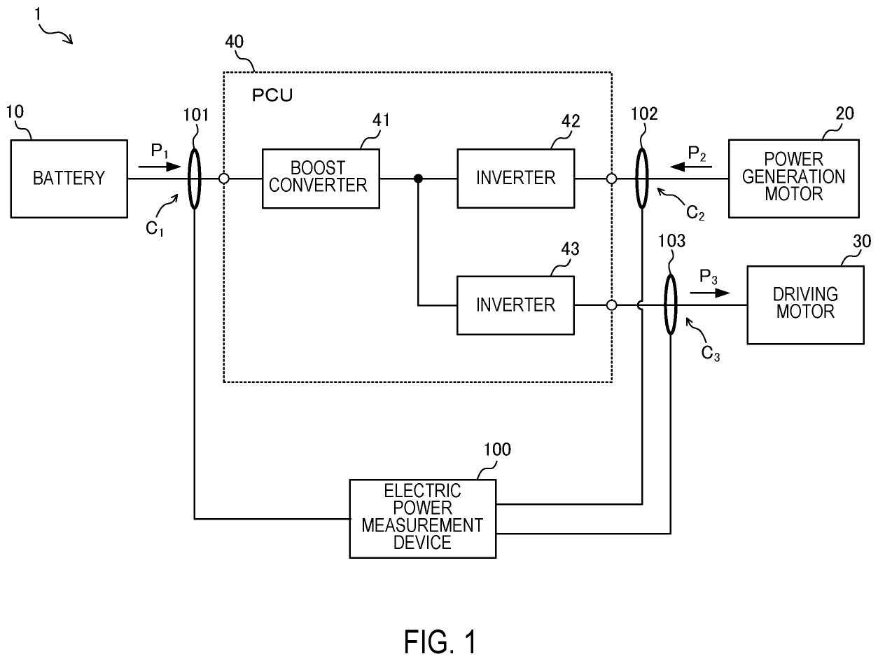

FIG. 1 is a diagram showing a configuration of an electric power transmission system provided with a measurement device in this embodiment.

An electric power transmission system 1 in this embodiment switches at least one of a transmission direction and path (a transmission pattern) at which electric power is transmitted in accordance with an operation state of the electric power transmission system 1 itself. For example, the electric power transmission system 1 is mounted on vehicles, trains, elevators, and so forth.

The electric power transmission system 1 is provided with a battery 10, a power generation motor 20, a driving motor 30, a PCU (a power control unit) 40, an electric power measurement device 100, and sensor units 101 to 103.

Each of the battery 10, the power generation motor 20, and the driving motor 30 is a device configured so as to be able to transmit the electric power and has at least one of a function of a power supplying device that supplies the electric power to other device and a function of a power receiving device that receives the electric power from the power supplying device. In the following, a device capable of transmitting the electric power in both of the directions and having both of the function of the power supplying device and the function of the power receiving device is also referred to as “a power receiving supplying device”.

The battery 10 is the power receiving supplying device that has a function of storing the electric power from the power generation motor 20 and has a function of discharging the electric power to the driving motor 30. The battery 10 in this embodiment inputs the stored electric power to the PCU 40.

Here, the electric power that is input from the battery 10 to the PCU 40 is shown as first electric power P1. DC voltage of the battery 10 is several hundreds [V], for example, and in this embodiment, a secondary battery having output voltage of about 300 [V] is used as the battery 10.

The power generation motor 20 is the power supplying device having a function of generating the electric power. The power generation motor 20 in this embodiment is formed of a three-phase AC motor, and the generated three-phase AC electrical power is input to the PCU 40.

The power generation motor 20 generates the electric power by being rotationally driven by an engine mounted on the vehicle, for example. Here, the electric power input from the power generation motor 20 to the PCU 40 is shown as second electric power P₂. The electric power P₂ in this embodiment is three-phase AC effective electric power.

The driving motor 30 is the power receiving supplying device having a function of converting the electric power to the motive force and a function of generating the electric power. The driving motor 30 in this embodiment is formed of the three-phase AC motor and is rotationally driven by the electric power supplied from the PCU 40. Here, the electric power output from the PCU 40 to the driving motor 30 is shown as third electric power P₃.

The PCU 40 is a device capable of transmitting the electric power in the both directions. The PCU 40 has a plurality of connecting terminals to which a plurality of external devices can be connected and outputs the electric power that has been input via the specific connecting terminal to the other connecting terminal.

The PCU 40 has a plurality of operation modes (operation states) that define how the electric power is to be transmitted and switches the intensity or the transmission direction of the electric power that is transmitted through channels between the external devices and the PCU 40 in accordance with the operation mode of the PCU 40 itself. In other words, the PCU 40 switches the transmission pattern for the electric power so as to be suitable with its operation mode.

In this embodiment, the PCU 40 is a target device that is a target of measurement of the electric power and functions as an electric power converting device that performs conversion of the electric power between DC electric power and the AC electrical power. The PCU 40 is mounted on the vehicle and switches the operation mode of the PCU 40 itself in accordance with a control signal indicating an operation state of the vehicle.

For example, in a case in which the vehicle is accelerated suddenly, the operation mode of the PCU 40 is shifted to a sudden acceleration mode, and the PCU 40 combines the electric power input from both of the battery 10 and the power generation motor 20 and outputs the combined electric power to the driving motor 30.

In addition, in a case in which the vehicle is decelerated or braked, the operation mode of the PCU 40 is shifted to a deceleration and braking mode, and the PCU 40 combines the electric power input from both of the power generation motor 20 and the driving motor 30 and outputs the combined electric power to the battery 10.

In a case in which the vehicle travels as normal, the operation mode of the PCU 40 is shifted to a normal travelling mode, and the PCU 40 outputs the electric power that has been input from the power generation motor 20 to both of the battery 10 and the driving motor 30 in a distributed manner.

Subsequently, the configuration of the PCU 40 will be described. The PCU 40 in this embodiment is provided with a boost converter 41, an inverter 42, and an inverter 43.

The boost converter 41 converts voltage of the input DC electric power to an output voltage value that is different from the input voltage value. For example, the boost converter 41 boosts the DC voltage of the electric power P₁ input from the battery 10 and applies the boosted DC voltage to the inverter 42 and the inverter 43. In addition, the boost converter 41 depresses the DC voltage of the electric power input from the inverter 42 or the inverter 43 and applies the depressed DC voltage to the battery 10.

The boost converter 41 in this embodiment boosts, for example, the DC voltage of about 300 [V] from the battery 10 to the DC voltage of about 600 [V] and outputs the DC voltage of about 600 [V] to the inverter 43.

The inverter 42 is a first inverter that converts the input electric power to alternating current or direct current. For example, the inverter 42 converts the AC voltage of the electric power P₂ input from the power generation motor 20 to the DC voltage and applies the converted DC voltage to the boost converter 41 and the inverter 43. The inverter 42 in this embodiment converts three-phase AC voltage from the power generation motor 20 to the DC voltage of about 600 [V] and applies the DC voltage of about 600 [V] to the inverter 43.

Similarly to the inverter 42, the inverter 43 is a second inverter converts the input electric power to the alternating current or direct current. For example, the inverter 43 converts the DC voltage of the electric power, which is obtained by combining the electric power Pi and the electric power P₂ input from the boost converter 41 and the inverter 42, respectively, to the AC voltage. The inverter 43 then outputs the electric power P₃ to the driving motor 30 by applying the converted AC voltage to the driving motor 30.

The inverter 43 in this embodiment converts the DC voltage of about 600 [V] of the combined electric power (P₁+P₂) from the boost converter 41 and the inverter 42 to the three-phase AC voltage and applies the converted three-phase AC voltage to the driving motor 30. Furthermore, the inverter 43 converts the three-phase AC voltage of the electric power input from the driving motor 30 to the DC voltage of about 600 [V] and applies the converted DC voltage of 600 [V] to the boost converter 41.

The electric power measurement device 100 is formed of one or more computers. The electric power measurement device 100 configures a measurement device that measures a state associated with the target device capable of transmitting the electric power in the single direction or in the dual directions via the channels, which are a plurality of transmission lines.

In this embodiment, the electric power measurement device 100 measures the operation state of the PCU 40 in a state in which it is connected to the plurality of channels. The plurality of channels in this description refer to a channel C₁ between the battery 10 and the PCU 40, a channel C₂ between the power generation motor 20 and the PCU 40, and a channel C₃ between the driving motor 30 and the PCU 40. The channel C₂ and the channel C₃ are each formed of a transmission line of a three-phase three wire system or a three-phase four wire system.

The electric power measurement device 100 computes an index indicating the transmission state of the PCU 40 on the basis of output signals from the sensor units 101 to 103. In the following, the index indicating the transmission state of the PCU 40 is referred to as “a transmission index”, and the transmission index includes, for example, the electric power efficiency, the electric power loss, and so forth.

In this embodiment, the sensor units 101 to 103 are provided separately from the electric power measurement device 100. Instead of this configuration, the sensor units 101 to 103 may be provided integrally with the electric power measurement device 100, or alternatively, the sensor units 101 to 103 may be incorporated into the electric power measurement device 100.

The sensor unit 101 is a detection device for detecting the DC electric power transmitted through the channel C₁. The sensor unit 101 is formed of, for example, a DC current sensor and a voltage sensor. The sensor unit 101 outputs a current detection signal indicating a current value of the current flowing through the channel C₁ and a voltage detection signal indicating a voltage value of the channel C₁ to the electric power measurement device 100.

The sensor unit 102 is a detection device for detecting the AC electrical power transmitted through the channel C₂. The sensor unit 102 is formed of, for example, three AC current sensors and three voltage sensors. The sensor unit 102 outputs phase current detection signals indicating the current values of the current flowing through the respective phases of the channel C₂ and a phase voltage detection signal indicating the voltage value of the channel C₂ to the electric power measurement device 100.

The sensor unit 103 is a detection device for detecting the AC electrical power transmitted through the channel C₃. Similarly to the sensor unit 102, the sensor unit 103 is formed of, for example, the three AC current sensors and the three voltage sensors. The sensor unit 103 outputs the phase current detection signals indicating the current values of the current flowing through the respective phases of the channel C₃ and the phase voltage detection signal indicating the voltage value of the channel C₃ to the electric power measurement device 100.

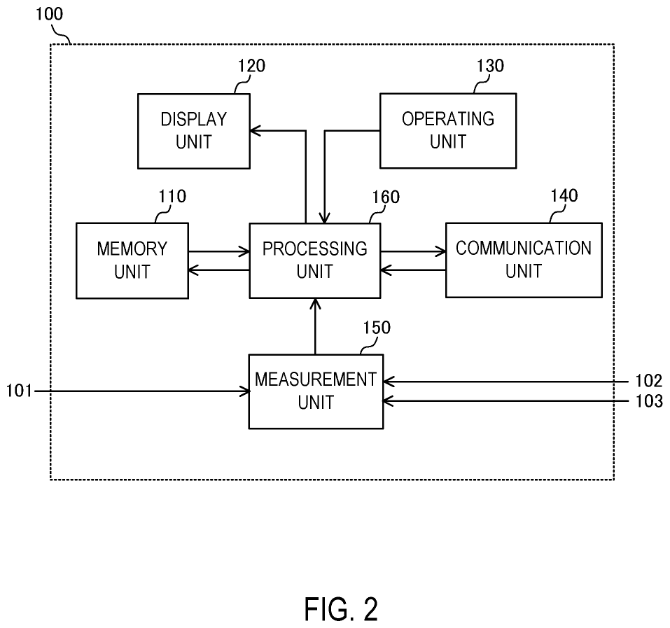

Next, the configuration of the electric power measurement device 100 will be described with reference to FIG. 2.

FIG. 2 is a block diagram showing a functional configuration of the electric power measurement device 100 in this embodiment.

The electric power measurement device 100 is the measurement device for measuring the state of the target device capable of transmitting the electric power. The electric power measurement device 100 is provided with a memory unit 110, a display unit 120, an operating unit 130, a communication unit 140, a measurement unit 150, and a processing unit 160.

The memory unit 110 is formed of a RAM (a Random Access Memory) and a ROM (a Read Only Memory). The memory unit 110 stores a control program for controlling the operation of the processing unit 160. In other words, the memory unit 110 is a non-transitory computer-readable storage medium in which a program for realizing the function of the electric power measurement device 100 in this embodiment is recorded.

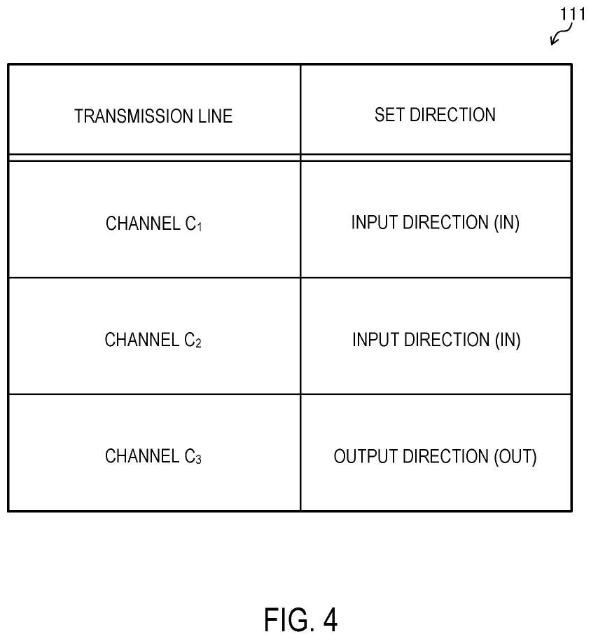

In this embodiment, the memory unit 110 stores reference information indicating reference directions that are the reference transmission directions of the electric power transmitted through a plurality of channels C₁ to C₃. This reference information is the information indicating whether the reference transmission direction of the electric power transmitted through each of the channels C₁ to C₃ is the input direction in which the electric power is input to the PCU 40 or the output direction in which the electric power is output from the PCU 40. In other words, the memory unit 110 forms a reference retaining circuit for retaining the reference information. A detail of the reference information will be described below with reference to FIG. 4.

The reference information stored in the memory unit 110 is generated by the operating unit 130, for example. The reference information may be stored in advance or may be obtained from the communication unit 140. In addition, the memory unit 110 stores a measurement data indicating a measurement result.

The display unit 120 reports a processing result from the processing unit 160 to a user by displaying the processing result. The display unit 120 is formed of, for example, an LED display, a liquid crystal display, and so forth. Instead of this configuration, the display unit 120 may be formed of a touch screen such that the user can visually recognize the information and such that the user can perform the operation.

The display unit 120 in this embodiment forms a notifying equipment that notifies the reference transmission direction of the electric power indicated by the reference information in the memory unit 110 for each of the channels C₁, C₂, and C₃. Specifically, the display unit 120 functions as a display equipment for displaying an image showing the reference transmission direction of the electric power indicated by the reference information for each of the channels C₁, C₂, and C₃.

The above-described notifying equipment includes, in addition to the display equipment, a sound output device that reports the reference transmission directions of the electric power for the respective channels C₁, C₂, and C₃ with sound, a light emitting device that is a part provided on each of the sensor units 101 to 103 and that specifies the reference transmission direction of the electric power, and so forth.

The operating unit 130 receives input information through the operation performed by the user. The operating unit 130 then outputs the received information to the processing unit 160. The operating unit 130 is formed of a mechanical push button, a touch panel, and so forth.

In this embodiment, the operating unit 130 receives the above-described reference information through an input operation performed by the user. In other words, the operating unit 130 forms an information acquisition circuit that acquires the reference information.

For example, the operating unit 130 is provided with a start button for starting measurement processing of the transmission index and a finish button for finishing the measurement processing. When the start button has been pressed, the operating unit 130 then outputs an instruction signal for executing the measurement processing to the processing unit 160, and when the finish button is pressed thereafter, the operating unit 130 outputs the instruction signal for finishing the measurement processing to the processing unit 160.

Although not illustrated, the communication unit 140 performs wireless or wired communication with an external processing device such as a mobile terminal, a server, and so forth. The communication unit 140 may receive, for example, the above-described instruction signal from the external processing device. In this case, the electric power measurement device 100 executes or stops the measurement processing in accordance with the instruction signal from the external processing device.

In addition, the communication unit 140 may send the measurement data to the external processing device. In this case, the external processing device may display the measurement data sent from the communication unit 140.

The communication unit 140 may receive the reference information stored in the memory unit 110 from the external processing device such as a mobile terminal, a server, and so forth. In this case, the communication unit 140 functions as the information acquisition circuit that acquires the reference information. The reference information received by the communication unit 140 is retained in the memory unit 110 through the processing unit 160.

The measurement unit 150 forms the electric power signal acquisition circuit that acquires a signal indicating the transmission direction and the intensity of the electric power transmitted to each of the channels C₁ to C₃. In the following, the signal indicating the transmission direction and the intensity of the electric power is referred to as a measurement signal.

In this embodiment, the measurement unit 150 measures the electric power of each of the channels C₁, C₂, and C₃ on the basis of the output signal from each of the sensor units 101 to 103. The measurement unit 150 acquires, as the above-described measurement signal, the electric power value of each of the channels C₁, C₂, and C₃ subjected to the measurement.

For example, the measurement unit 150 calculates, as the output signal from the sensor unit 102, the detection signal output from each of the AC current sensors and the voltage sensors of the respective phases and calculates the electric power value of the effective electric power of the channel C₂ by using each detection signal thus acquired. Similarly, the measurement unit 150 calculates the electric power value of the effective electric power of the channel C₃ by acquiring each detection signal from the sensor unit 103, which is obtained from the AC current sensors and the voltage sensors of the respective phases.

Alternatively, the measurement unit 150 may be provided with a shunt resistance for each of the channels C₁ to C₃, and the channel itself may be electrically connected to the shunt resistance by a cable for each of the channels C₁, C₂, and C₃. In this case, the electric power is detected by using voltage of the cable and voltage between both ends of the shunt resistance for each of the channels C₁, C₂, and C₃.

The processing unit 160 forms a processor serving as a computing unit that computes at least one of the input electric power and the output electric power of the target device capable of transmitting the electric power on the basis of the sign indicating the direction of the measurement signal with respect to the reference transmission direction of the electric power of each of the channels C₁, C₂, and C₃ indicated by the reference information in the memory unit 110. In this embodiment, the PCU 40 corresponds to the target device. In addition, types of the sign of the measurement signal include, for example, positive (plus), negative (minus), and so forth.

Specifically, the processing unit 160 determines the sign of the measurement signal for each of the channels C₁, C₂, and C₃ with respect to the reference transmission direction of the electric power of each of the channels C₁, C₂, and C₃ indicated by the reference information. The processing unit 160 determines whether the actual transmission direction for each of the channels C₁, C₂, and C₃ is the input direction or the output direction for the target device on the basis of the determined type of the sign.

The processing unit 160 determines that, for each of the channels C₁, C₂, and C₃, transmitted electric power of the target device transmitted through each of the channels is the input electric power or the output electric power on the basis of the specified result. By doing so, the processing unit 160 can compute the input electric power or the output electric power for the target device.

A computed value of the above-described input electric power includes, for example, the electric power value of the input electric power of each of the channels connected to the target device and the total sum of the input electric power for all channels. The same applies to the computed value of the output electric power.

The processing unit 160 in this embodiment computes the transmission index of the PCU 40 on the basis of the total sum of the input electric power and the total sum of the output electric power for the PCU 40. The transmission index includes, as described above, the electric power efficiency and the electric power loss.

The processing unit 160 records the transmission index thus computed and the input electric power and the output electric power, which are used for the calculation of the transmission index, to the memory unit 110 as the measurement data. In addition, the processing unit 160 outputs the measurement data to the communication unit 140 in accordance with a communication request from the external processing device.

Furthermore, the processing unit 160 outputs the measurement data to the display unit 120. By doing so, the display unit 120 generates image data for displaying the measurement data in a predetermined type and displays the image data thus generated on the screen.

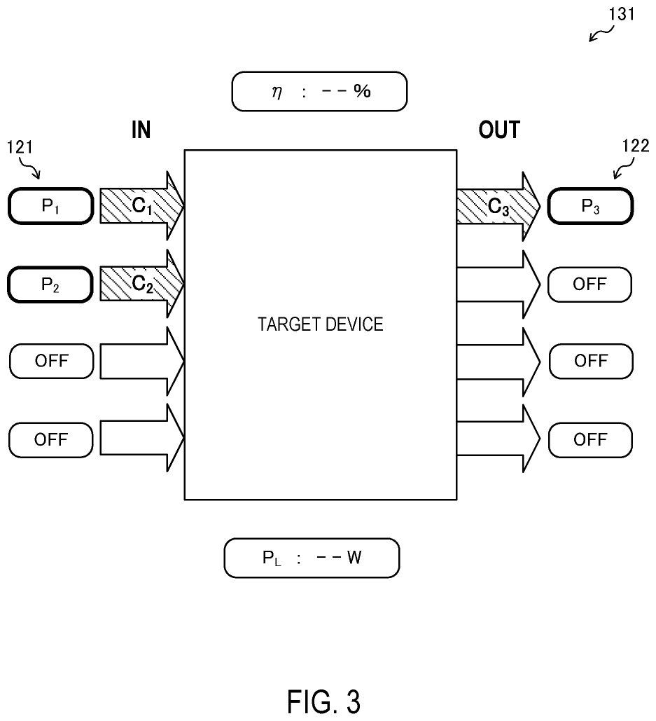

Next, a setting procedure for setting the reference information stored in the memory unit 110 will be described with reference to FIG. 3.

FIG. 3 is a diagram showing an example setting screen for setting the reference information in this embodiment. In this example, the electric power measurement device 100 can measure the electric power of up to eight channels. In the following, the channel for inputting the electric power to the PCU 40 that is the target device is referred to as “an input channel”, and the channel for outputting the electric power from the PCU 40 is referred to as “an output channel”.

As shown in FIG. 3, in a setting image 131 displayed on the display unit 120, four setting regions 121 for the input channels and four setting regions 122 for the output channels are provided.

For each of the setting regions 121 and the setting regions 122, it is possible to set a single item selected from the electric power P₁ to P₈ transmitted through the eight channels and “OFF” meaning that no channel is connected to the target device. In addition, by setting any one of the electric power P₁ to P₈, channel numbers are sequentially given to the setting regions 121 and the setting regions 122.

In example, the electric power P₁ of the channel C₁ is set for the setting region 121 for a first input channel, and the electric power P₂ of the channel C₂ is set for the setting region 121 for a second input channel. By doing so, the reference transmission direction of the electric power transmitted through the channel C₁ is set as the input direction, and the reference transmission direction of the electric power transmitted through the channel C₂ is set as the input direction.

In addition, the P₃ of the channel C₃ is set for the setting region 122 for a first output channel. By doing so, the reference transmission direction of the electric power transmitted through the channel C3 is set as the output direction. OFF is set for other setting regions 121 and setting regions 122.

As described above, the reference transmission direction of each of the electric power P₁, P₂, and P₃ for the PCU 40 is set for each of the channels C₁, C₂, and C₃. The processing unit 160 of the electric power measurement device 100 then calculates the electric power efficiency η and the electric power loss P_{L} of the PCU 40 on the basis of the reference transmission direction of the electric power set for each of the channels C₁ to C₃ and the sign of a measured value of each of the electric power P₁ to P₃. The results of the calculations are displayed in the respective regions of the electric power efficiency η and the electric power loss P_{L}.

In addition, the display unit 120 displays the setting image 131 as an image for showing the reference transmission direction of the electric power indicated by the reference information for each of the channels C₁, C₂, and C₃. By doing so, it is possible to avoid accidental attachment of the sensor units 101 to 103 to the respective channels C₁ to C₃ at incorrect position and direction by the user of the electric power measurement device 100.

In the example shown in FIG. 3, although a description is given of an example in which the input channel or the output channel is determined by setting any of the electric power P₁ to P₈ for each of the setting regions 121 and the setting regions 122, the present invention is not limited thereto.

For example, for each of the channels that can be connected to the PCU 40, one type of the channel may be selected from “the input channel” and “the output channel” and one sign of the electric power may be selected from “plus” and “minus”.

In this case, when “the input channel” and “plus” are selected, the channel is set as “the input channel”, and when “the input channel” and “minus” are selected, the channel is set as “the output channel”. The reference information is generated in accordance with the type of the channel set as described above.

Next, a content of the reference information stored in the memory unit 110 will be described with reference to FIG. 4.

FIG. 4 is a diagram showing an example of a type of reference information 111 in this embodiment. In the reference information 111, one or more transmission line(s) to be connected to the PCU 40 and the reference transmission direction(s) of the transmission line(s) for the PCU 40 are shown.

The reference transmission direction of the transmission line described above refers to the reference direction of the electric power that is transmitted through the transmission line for the PCU 40. In this embodiment, because the reference transmission direction is set in advance by the operating unit 130, it will be hereinafter referred to as “the set direction”. The set direction may also be set in advance by the operating unit of the external processing device.

Here, as shown in FIG. 1, the channel C₁ and the channel C₂ are both set as the input direction for the PCU 40, and the channel C₃ is set as the output direction for the PCU 40.

Although the reference transmission directions of the electric power that are different from each other are set in the reference information 111, the present invention is not limited thereto, and for example, all of the set directions may be the same, or the set directions may be set as the directions so as to be opposite from the directions shown in FIG. 3.

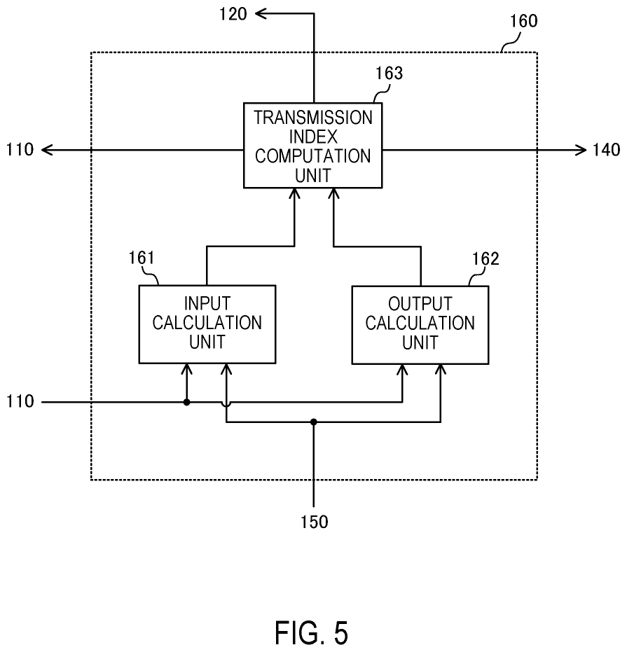

Next, a function of the processing unit 160 in the electric power measurement device 100 will be described with reference to FIG. 5.

FIG. 5 is a block diagram showing the functional configuration of the processing unit 160 in this embodiment. The processing unit 160 is provided with an input calculation unit 161, an output calculation unit 162, and a transmission index computation unit 163.

The input calculation unit 161 forms a second adder that obtains the sum of the absolute value of the electric power of the channel in which the measurement signal is positive among the channels in which the set direction is the input direction and the absolute value of the electric power of the channel in which the measurement signal is negative among the channels in which the set direction is the output direction.

In this embodiment, the input calculation unit 161 reads out the predetermined reference information from the memory unit 110 and acquires the reference transmission direction of the electric power of each of the channels C₁, C₂, and C₃ indicated by the reference information as the set directions.

From all of the channels C₁ to C₃, the input calculation unit 161 selects the channels C₁ and C₂ in which the acquired set direction is the input direction as the input channel and selects the channel C₃ in which the acquired set direction is the output direction as the output channel.

In addition, for each of the channels C₁, C₂, and C₃, the input calculation unit 161 specifies whether the sign of the electric power value measured by the measurement unit 150 is plus or minus.

For each of the input channels C₁ and C₂ selected, in a case in which the sign of the measured electric power value is plus, the input calculation unit 161 determines that the electric power value thereof corresponds to the input electric power because the actual transmission direction is the same as the set direction (IN).

On the other hand, for each of the selected output channel C₃, in a case in which the sign of the measured electric power value is minus, the input calculation unit 161 determines that the absolute value of the electric power value thereof corresponds to the input electric power because the actual transmission direction is opposite from the set direction (OUT).

The input calculation unit 161 then calculates the electric power value of each input electric power and the total sum of the input electric power for the PCU 40 by using the absolute value of the electric power value of each of the channels that are determined to correspond to the input electric power.

Subsequently, a function of the output calculation unit 162 will be described.

The output calculation unit 162 forms a first adder that obtains the sum of the absolute value of the electric power of the channel in which the measurement signal is negative among the channels in which the set direction is the input direction and the absolute value of the electric power of the channel in which the measurement signal is positive among the channels in which the set direction is the output direction.

Similarly to the input calculation unit 161, the output calculation unit 162 acquires, as the set direction, the reference transmission direction of the electric power of each of the channels C₁, C₂, and C₃ indicated by the reference information read out from the memory unit 110.

Furthermore, the output calculation unit 162 selects the input channels C₁ and C₂, the acquired set direction of which is the input direction, from all of the channels C₁ to C₃ and selects the output channel C₃, the acquired set direction of which is the output direction. For each of the channels C₁, C₂, and C₃, the output calculation unit 162 specifies whether the sign of the electric power value measured by the measurement unit 150 is plus or minus.

In this embodiment, for each of the input channels C₁ and C₂ selected, in a case in which the sign of the measured electric power value is minus, the output calculation unit 162 determines that the absolute value of the electric power value thereof corresponds to the output electric power. On the other hand, for the output channel C₃ selected, in a case in which the sign of the measured electric power value is plus, the output calculation unit 162 determines that the electric power value thereof corresponds to the output electric power.

The output calculation unit 162 then calculates the electric power value of each output electric power and the total sum of the output electric power for the PCU 40 by using the absolute value of the electric power value of each of the channels that is determined to correspond to the output electric power.

Subsequently, a function of the transmission index computation unit 163 will be described.

The transmission index computation unit 163 forms a calculator serving as index computing unit that computes the transmission index that indicates the transmission state of the target device on the basis of the total sum obtained by the output calculation unit 162 and the total sum obtained by the input calculation unit 161.

The transmission index computation unit 163 in this embodiment obtains the electric power efficiency of the PCU 40 by dividing the total sum of the output electric power of the PCU 40 corresponding to the target device by the total sum of the input electric power. Furthermore, the transmission index computation unit 163 obtains the electric power loss of the PCU 40 by subtracting the total sum of the output electric power from the total sum of the input electric power of the PCU 40.

As described above, for each of the channels C₁ to C₃, the processing unit 160 in this embodiment computes the transmission index, such as the electric power efficiency, the electric power loss, and so forth of the PCU 40, on the basis of the set direction indicated by the reference information and the sign of the measured value of the electric power output from the measurement unit 150.

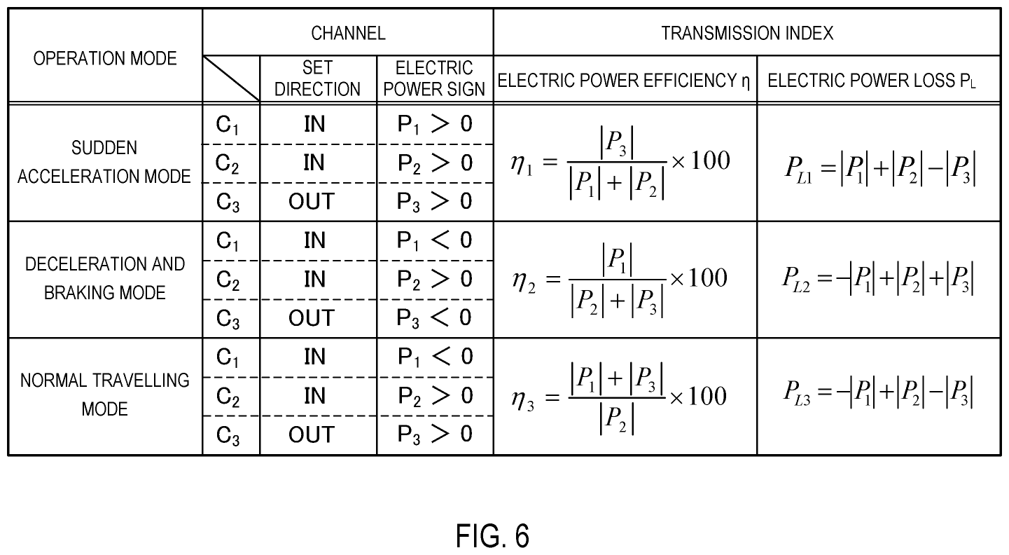

Next, procedures for computing the transmission indices performed by the processing unit 160 along with the switching of the operation mode by the PCU 40 will be described with reference to FIG. 6.

FIG. 6 is a diagram for explaining a computation formula of the electric power efficiency η and the electric power loss P_{L} that are changed in accordance with the set direction of the channel and the sign of measured electric power for every operation mode of the PCU 40. In this example, as shown in FIG. 4, for the PCU 40, the reference transmission directions of the electric power of the channels C₁ and C₂ are set as the input direction, and the reference transmission direction of the electric power of the channel C₃ is set as the output direction.

For example, as the PCU 40 is shifted to the sudden acceleration mode, all of the signs of the measured values of the electric power P₁, P₂, and P₃ become plus with respect to the set directions of the respective channels C₁, C₂, and C₃. Therefore, the electric power P₁ and P₂ of the respective input channels C₁ and C₂ correspond to the input electric power for the PCU 40, and the electric power P₃ of the output channel C₃ corresponds to the output electric power from the PCU 40.

Therefore, the electric power efficiency η₁ of the PCU 40 is obtained by dividing the absolute value of the electric power P₃ corresponding to the output electric power by the total sum of the respective absolute values of the electric power P₁ and the electric power P₂ corresponding to the input electric power. In addition, the electric power loss P_{L1} of the PCU 40 is obtained by subtracting the absolute value of the electric power P₃ corresponding to the output electric power from the total sum of the absolute values of the electric power P₁ and the electric power P₂ corresponding to the input electric power.

In addition, as the PCU 40 is shifted to the deceleration and braking mode, both of the signs of the measured values of the electric power P₁ and P₃ with respect to the set directions of the respective channels C₁ and C₃ become minus, and the sign of the measured value of the electric power P₂ with respect to the set direction of the channel C₂ becomes plus.

Thus, because the sign is minus with respect to the set direction (IN), the electric power P₁ of the input channel C₁ corresponds to the output electric power from the PCU 40, and because the sign is plus with respect to the set direction (IN), the electric power P₂ of the input channel C₂ corresponds to the input electric power of the PCU 40. Because the sign is minus with respect to the set direction (OUT), the electric power P₃ of the output channel C₃ corresponds to the input electric power of the PCU 40.

Therefore, the electric power efficiency η₂ of the PCU 40 is obtained by dividing the absolute value of the electric power P₁ corresponding to the output electric power by the total sum of the respective absolute values of the electric power P₂ and the electric power P₃ corresponding to the input electric power. In addition, the electric power loss P_{L2} of the PCU 40 is obtained by subtracting the absolute value of the electric power P₁ corresponding to the output electric power from the total sum of the absolute values of the electric power P₂ and the electric power P₃ corresponding to the input electric power.

Furthermore, as the PCU 40 is shifted to the normal travelling mode, the sign of the measured value of the electric power P₁ with respect to the set direction of the channel C₁ becomes minus, and both of the signs of the measured values of the electric power P₂ and P₃ with respect to the set directions of the respective channels C₂ and C₃ become plus.

Thus, because the sign is minus with respect to the set direction (IN), the electric power P₁ of the input channel C₁ corresponds to the output electric power from the PCU 40, and because the sign is plus with respect to the set direction (IN), the electric power P₂ of the input channel C₂ corresponds to the input electric power of the PCU 40. Because the sign is plus with respect to the set direction (OUT), the electric power P₃ of the output channel C₃ corresponds to the output electric power from the PCU 40.

Therefore, the electric power efficiency η₃ of the PCU 40 is obtained by dividing the total sum of the respective absolute values of the electric power P₁ and the electric power P₃ corresponding to the output electric power by the total sum of the absolute value of the electric power P₂ corresponding to the input electric power. In addition, the electric power loss P_{L3} of the PCU 40 is obtained by subtracting the total sum of the respective absolute values of the electric power P₁ and the electric power P₃ corresponding to the output electric power from the total sum of the absolute value of the electric power P₂ corresponding to the input electric power.

Although the procedures for computing the transmission indices are shown in FIG. 6 for each of three operation modes, the present invention is not limited thereto. For example, in a case in which the number of channels that can be connected to the PCU 40 is N (a natural number equal to or greater than two), the number of the operation modes of the PCU 40 becomes 2^{N} at its maximum.

In the PCU 40 having 2^{N} number of operation modes, even in a case in which 2^{N} number of computation formulae are not prepared in advance, according to this embodiment, it is possible to suitably compute the transmission index in accordance with the operation mode of the PCU 40 at the present.

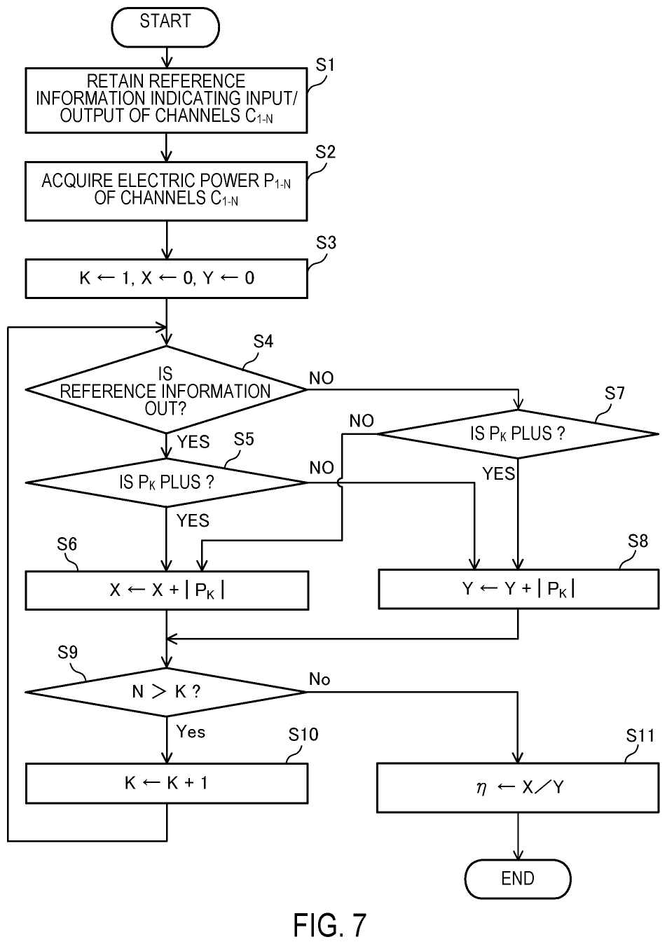

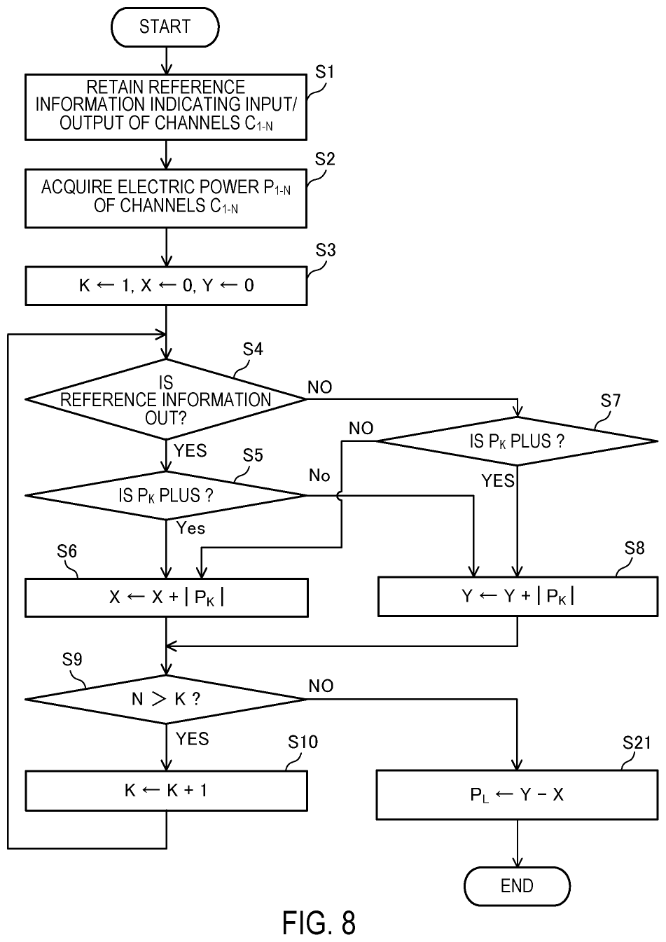

Next, operation of the computer forming the electric power measurement device 100 will be described with reference to FIGS. 7 and 8.

FIG. 7 is a flowchart showing an example processing procedure of an efficiency computing method for computing the electric power efficiency η of the target device capable of transmitting the electric power. In this example, the total number of channels connected to the target device is described as N, the all of the channels is described as C_{1-N}, and the all electric power transmitted through the respective channels is described as P_{1-N}.

In step S1, the electric power measurement device 100 retains the reference information indicating the input/output through each of the channels C_{1-N} in the memory unit 110. The reference information retained in the memory unit 110 is the information indicating whether each of the reference transmission directions of the electric power transmitted through the channels C_{1-N} is the input direction in which the electric power is input to the target device or the output direction in which the electric power is output from the target device.

As shown in FIGS. 3 and 4, the electric power measurement device 100 in this embodiment generates, via the operating unit 130, the reference information indicating the set direction of each of the electric power P₁, the electric power P₂, and the electric power P₃ of the channels C₁ to C₃. The electric power measurement device 100 then records (retains) thus-generated reference information to the memory unit 110.

In step S2, the electric power measurement device 100 acquires the measurement signals that indicate the respective transmission directions and the intensities of the electric power P_{1-N} transmitted to the channels C_{1-N}. The electric power measurement device 100 in this embodiment measures the respective electric power values of the channels C₁ to C₃ on the basis of the output signals from the sensor units 101 to 103.

In step S3, the electric power measurement device 100 sets an initial value “1” for a channel number K. Furthermore, the electric power measurement device 100 sets an initial value “0” for each of the output electric power X and the input electric power Y for the target device.

In step S4, the electric power measurement device 100 determines whether or not the set direction of the channel Cₖ indicated by the reference information is the output direction (OUT). When the electric power measurement device 100 has determined that the set direction of the channel C_{K} is the output direction (OUT), the process proceeds to step S5.

In step S5, the electric power measurement device 100 determines whether or not the sign of the measured value of the electric power P_{K} transmitted to the channel C_{K} is plus. When the measured value of the electric power P_{K} is equal to 0 (zero), the electric power measurement device 100 may determine that the sign of the measured value is plus or may determine that the sign is minus.

When the electric power measurement device 100 determined that the sign of the measured value of the electric power P_{K} is not plus, because the electric power P_{K} then corresponds to the input electric power, the process proceeds to step S8. On the other hand, when the electric power measurement device 100 has determined that the sign of the measured value of the electric power P_{K} is plus, because the electric power P_{K} then corresponds to the output electric power, the process proceeds to step S6.

In step S6, the electric power measurement device 100 sets, for the output electric power X, the sum of the output electric power X and the absolute value of the measured value of the electric power P_{K}.

In addition, in the electric power measurement device 100, when it is determined that the set direction of the channel C_{K} is not the output direction (OUT) in step S4, the process proceeds to step S7.

In step S7, the electric power measurement device 100 determines whether or not the sign of the measured value of the electric power P_{K} transmitted to the channel C_{K} is plus.

When the electric power measurement device 100 has determined that the sign of the measured value of the electric power P_{K} is not plus, because the electric power P_{K} then corresponds to the output electric power, the process proceeds to step S6. On the other hand, when the electric power measurement device 100 has determined that the sign of the measured value of the electric power P_{K} is plus, because the electric power P_{K} then corresponds to the input electric power, the process proceeds to step S8.

In step S8, the electric power measurement device 100 sets, for the input electric power Y, the sum of the input electric power Y and the absolute value of the measured value of the electric power P_{K}.

As described above, in steps S4 to S8, the electric power measurement device 100 classifies the transmitted electric power of each of the channels C_{1-N} into the input electric power Y or the output electric power X on the basis of the set directions of the channels C_{1-N} indicated by the reference information and the signs of the measured values of the electric power P_{1-N}.

Subsequently, in step S9, the electric power measurement device 100 determines whether or not the channel number K is smaller than the maximum value N. When the electric power measurement device 100 has determined that the channel number K is smaller than the maximum value N, the process proceeds to step S10.

In step S10, the electric power measurement device 100 sets a value obtained by adding “1” to the channel number K for the channel number K. Then, the electric power measurement device 100 repeats a series of processing of steps S4 to S8 until the channel number K reaches the maximum value N.

In the electric power measurement device 100, when it is determined that the channel number K is equal to or greater than the maximum value N in step S9, the process proceeds to step S11.

In step S11, the electric power measurement device 100 sets a value obtained by dividing the output electric power X by the input electric power Y for the electric power efficiency η of the target device. A series of processing procedures for the efficiency computing method are terminated.

As described above, the electric power measurement device 100 computes the electric power efficiency η on the basis of the set directions of the channels C_{1-N} indicated by the reference information and the measured values of the electric power P_{1-N}.

The electric power measurement device 100 in this embodiment determined whether the electric power P_{K} is the input electric power Y or the output electric power X on the basis of the set direction of the channel C_{K} and the measured value of the electric power P_{K}. Instead, the electric power measurement device 100 may classify the transmission state of the electric power Pk into the input electric power, the output electric power, and the electric power stopped (zero).

FIG. 8 is a flowchart showing an example processing procedure for a loss computation method for computing the electric power loss P_{L} of the target device.

In the loss computation method, the process in step S11 in the efficiency computing method shown in FIG. 7 is replaced with a process in step S21. Therefore, only the process in step S21 will be described in detail. Because other processes are the same as those in the processing procedure of the efficiency computing method, the same reference numerals are assigned as the processes in the efficiency computing method, and a detailed description thereof will be omitted.

In step S21, the electric power measurement device 100 sets a value obtained by subtracting the output electric power X obtained in step S6 from the input electric power Y obtained in step S8 for the electric power loss P_{L} of the target device. A series of processing procedures for the loss computing method are terminated.

As described above, the electric power measurement device 100 computes the electric power loss P_{L} on the basis of the set directions of the channels C_{1-N} indicated by the reference information and the measured values of the electric power P_{1-N}.

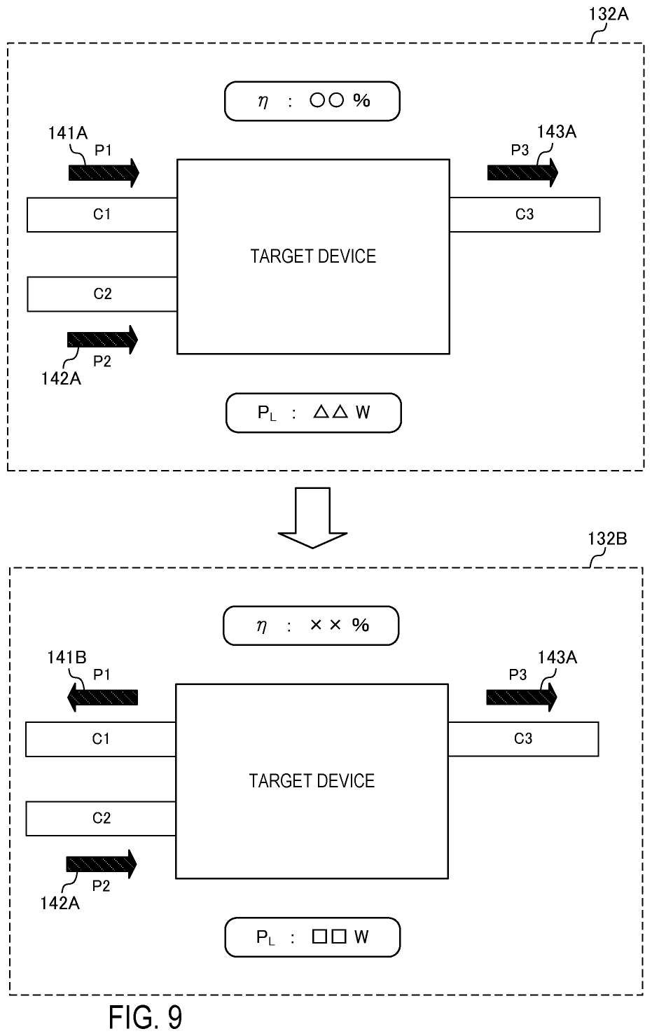

Next, the operation of the display unit 120 forming the electric power measurement device 100 will be described with reference to FIG. 9.

FIG. 9 is a diagram showing an example of a display screen for displaying the transmission state of the PCU 40 in this embodiment. Here, in the display screen of the display unit 120, a shift of a displayed image when the PCU 40 is switched from the sudden acceleration mode to the normal travelling mode is shown.

FIG. 9 shows a displayed image 132A at the time when the PCU 40 is shifted to the sudden acceleration mode and a displayed image 132B at the time when the PCU 40 is shifted to the normal travelling mode.

In the displayed image 132A, as shown in FIG. 6, transmission directions 141A, 142A, and 143A of the respective channels C₁, C₂, and C₃ are the same as the respective set directions indicated by the reference information.

On the other hand, as shown in FIG. 6, the value of the electric power P₁ transmitted to the channel C₁ is minus with respect to the set direction indicated by the reference information. Thus, in the displayed image 132B, transmission direction 141B of the channel C₁ is set as the direction opposite from the set direction indicated by the reference information.

As described above, for each of the channels C₁, C₂, and C₃, the display unit 120 displays, as the image for showing the set directions (the reference transmission directions of the electric power) indicated by the reference information, the transmission directions 141A, 142A, and 143A. The display unit 120 then changes the transmission directions 141A, 142A, and 143A shown in the image in accordance with the change in the sign that indicates the direction of the measurement signal indicating the transmission directions and the intensities of the electric power P₁, P₂, and P₃ with reference to the set directions of the respective channels C₁, C₂, and C₃ indicated by the reference information.

Operational advantages according to this embodiment described above will be described.

The electric power measurement device 100 in this embodiment is the measurement device that is configured to measure the state of the PCU 40 that corresponds to the target device capable of switching at least one transmission direction of the channel among the transmission directions of the electric power transmitted through the plurality of channels. The electric power measurement device 100 is provided with the memory unit 110 serving as the reference retaining circuit retaining the reference information. The reference information is the information that indicates, for each of the channels C₁, C₂, and C₃, whether the set direction used as the reference transmission direction of the electric power transmitted through the channel is the input direction in which the electric power is input to the PCU 40 or the output direction in which the electric power is output from the PCU 40.

The electric power measurement device 100 is provided with the measurement unit 150 serving as the electric power signal acquisition circuit that ac quires the measurement signal for each of the channels C₁ to C₃ indicated by the reference information. The measurement signal is the signal that indicates, for each of the channels C₁, C₂, and C₃, the transmission direction and the intensity of the electric power transmitted through the channel. Furthermore, the electric power measurement device 100 is provided with the processing unit 160 serving as the processor that computes at least one of the input electric power and the output electric power of the PCU 40 on the basis of the sign indicating the direction of the measurement signal with respect to the set direction of each of the channels C₁, C₂, and C₃ indicated by the reference information.

In addition, the measurement method in this embodiment is the measurement method that measures the state of the target device capable of switching at least one transmission direction of the channel among the transmission directions of the electric power transmitted through the plurality of channels. This measurement method includes a reference retaining step (S1) in which the above-described reference information is retained in the memory unit 110 and an electric power signal acquisition step (S2) in which the measurement signal indicating, for each of the channels C₁ to C₃, the transmission direction and the intensity of the electric power transmitted through the channel indicated by the reference information is acquired. Furthermore, the above-described measurement method includes computing steps (S3 to S10) in which at least one of the input electric power and the output electric power of the PCU 40 is computed on the basis of the sign that indicates the direction of the measurement signal with respect to the set direction (the reference transmission direction) of each of the channels C₁, C₂, and C₃ indicated by the reference information.

Furthermore, the program to be executed by the computer forming the electric power measurement device 100 in this embodiment is the program recorded in the storage medium forming the memory unit 110. This program includes the reference retaining step (S1) in which the reference information is retained and the electric power signal acquisition step (S2) in which the measurement signal of each of the channels C₁ to C₃ indicated by the reference information is acquired. Furthermore, the above-described program includes the computing steps (S3 to S10) in which at least one of the input electric power and the output electric power of the PCU 40 is computed on the basis of the sign that indicates the direction of the measurement signal with respect to the set direction of each of the channels C₁, C₂, and C₃ indicated by the reference information.

According to these configurations, for each of the channels C₁, C₂, and C₃, the sign of the measurement signal is identified on the basis of the set direction of the electric power indicated by the reference information and of the intensity of the electric power indicated by the measurement signal. By taking the sign of the measurement signal with respect to the set direction of each of the channels C₁, C₂, and C₃ indicated by the reference information into consideration, it is possible to determine whether the transmitted electric power through each of the channels C₁, C₂, and C₃ for the PCU 40 is the input electric power or the output electric power.

By doing so, because the sign of the measurement signal of the specific channel among the channels C1 to C3 is switched when the operation mode of the PCU 40 is switched, it is possible to suitably classify the electric power of the specific channel as corresponding to any of zero, the input electric power, and the output electric power. Thus, it is also possible to obtain the total sum of the input electric power or the total sum of the output electric power for the PCU 40.

Therefore, according to this embodiment, the electric power measurement device 100 can appropriately measure the state of the PCU 40 in accordance with the operation mode of the PCU 40.

Here, a general procedure for appropriately measuring the state of the target device capable of transmitting the electric power will be described. There is a device in which the transmission direction or the path of the electric power transmitted through the respective channels is switched when the operation mode of the target device is switched to another operation mode as the PCU 40. In such a target device, assuming the number of channels is N (a natural number equal to or greater than two), the number of the transmission patterns becomes 2^{N} at its maximum. For example, when the number of the channels is three, the number of the transmission patterns becomes eight at its maximum.

Thus, in order to measure the transmission state for the target device having 2^{N} number of operation modes, 2^{N} number of computation formulae are generally prepared in advance. In this case, in the target device in which the transmission direction of the electric power is automatically switched at one or more channels without intention of the measurer, in a state in which the target device is being operated, it is difficult to suitably determine which of the values obtained from the computation formulae should be selected at that specific time point. Thus, it was difficult to display the measurement result in real time.

In contrast, according to this embodiment, by using the reference information, which indicates the set direction of each channel, retained in the memory unit 110, the sign that indicates the direction of the measurement signal with respect to the set direction of each channel is specified. By identifying the sign of the measurement signal, it is possible to determine whether the transmitted electric power of each channel is the input electric power of the target device, the output electric power of the target device, or zero. Therefore, the electric power measurement device 100 in this embodiment can measure the state of the target device without preparing numerous number of computation formulae applicable to the transmission patterns of the target device in advance. In addition, it is possible to display the measurement results in real time.

For example, in the processing unit 160, the intensities of the electric power indicated by a plurality of measurement signals in the same direction are cumulated on the basis of the signs of the measurement signals with respect to the set directions of the respective channels C₁, C₂, and C₃. By doing so, even when the transmission direction of the electric power is switched by the PCU 40, it is possible to correctly compute the total sum of the input electric power or the total sum of the output electric power of the PCU 40.

In addition, the processing unit 160 in this embodiment is provided with the output calculation unit 162 serving as the first adder configured to obtain sum of the absolute value of the electric power of the channel in which the measurement signal is positive among the channels in which the set direction is the output direction and the absolute value of the electric power of the channel in which the measurement signal is negative among the channels in which the set direction is the input direction.

Furthermore, the processing unit 160 is provided with the input calculation unit 161 serving as the second adder configured to obtain the sum of the absolute value of the electric power of the channel in which the measurement signal is positive among the channels in which the set direction is the input direction and the absolute value provided of the electric power of the channel in which the measurement signal is negative among the channels in which the set direction is the output direction. The processing unit 160 is provided with the transmission index computation unit 163 serving as the calculator configured to compute the transmission index indicating the transmission state of the PCU 40 on the basis of the sum obtained by the output calculation unit 162 and the sum obtained by the input calculation unit 161.

According to this configuration, the processing unit 160 can obtain the transmission state of the electric power in the PCU 40 because the total sum of the input electric power and the total sum of the output electric power in the PCU 40 are obtained.

In addition, the transmission index computation unit 163 in this embodiment is configured to compute the electric power efficiency η of the PCU 40 by dividing the sum obtained by the output calculation unit 162 by the sum obtained by the input calculation unit 161. As described above, the transmission index computation unit 163 can obtain the electric power efficiency η of the PCU 40 by using the total sum of the input electric power and the total sum of the output electric power of the PCU 40.

In addition, the transmission index computation unit 163 in this embodiment is configured to compute the electric power loss P_{L} of the PCU 40 by subtracting the sum obtained by the output calculation unit 162 from the sum obtained by the input calculation unit 161. As described above, the transmission index computation unit 163 can obtain the electric power loss P_{L} of the PCU 40 by using the total sum of the input electric power and the total sum of the output electric power of the PCU 40.

In addition, the electric power measurement device 100 in this embodiment is provided with the sensor units 101 to 103 serving as a plurality of sensors configured to detect the intensity of the electric power transmitted through the channels C₁ to C₃. Furthermore, the electric power measurement device 100 is provided with the display unit 120 serving as the notifying equipment configured to notify the set direction of each of the channels C₁, C₂, and C₃ indicated by the reference information.

According to this configuration, it is possible to suppress the accidental attachment of the sensor units 101 to 103 to the respective channels C₁ to C₃ at incorrect positions and directions. By doing so, it is possible to avoid a situation in which the transmission index of the PCU 40 cannot be calculated correctly due to incorrect connection of the sensor units 101 to 103.

Especially, for the AC current sensors forming the sensor units 101 to 103, a current sensor needs to be attached such that the value of the current flowing along the set direction of each of the channels C₁, C₂, and C₃ indicated by the reference information becomes plus. However, if the current sensor is attached such that the value of the current flowing in the set direction becomes minus, the electric power efficiency η and the electric power loss P_{L} are calculated incorrectly. Therefore, by reporting the set direction of each of the channels C₁, C₂, and C₃ indicated by the reference information to the user, it is possible to avoid attachment of the current sensor in the incorrect direction by the user.

The notifying equipment may be formed by using an output device such as a speaker outputting sound instead of using the display unit 120. For example, the output device outputs, as sound, an announcement such as “Please attach the current sensor to be attached to the channel C₁ such that the current flowing towards a measurement target device becomes plus.” in accordance with the reference information stored in the memory unit 110.

In addition, the electric power measurement device 100 in this embodiment is provided with the display unit 120 serving as the display equipment configured to display the image showing the set direction indicated by the reference information for each of the channels C₁, C₂, and C₃ connected to the PCU 40. The display unit 120 is configured to change the set direction shown in the image to the direction opposite from the set direction in accordance with change in the sign indicating the direction of the measurement signal with respect to the set direction indicated by the reference information for each of the channels C₁, C₂, and C₃.

According to this configuration, it is possible to display the actual transmission direction of the electric power transmitted through each of the channels C₁, C₂, and C₃ in real time. By doing so, the flow of the electric power for the PCU 40 can be ascertained by the user in real time, and so, the operation mode of the PCU 40 at the present can be ascertained.

Although the embodiments of the present invention have been described in the above, the above-mentioned embodiments merely illustrate a part of application examples of the present invention, and the technical scope of the present invention is not intended to be limited to the specific configurations of the above-described embodiments.

In this embodiment, the target device capable of transmitting the electric power has been described as exemplified in the PCU 40 to which a plurality of channels C₁ to C₃ are connected; however, the present invention is not limited thereto.

For example, the battery 10 shown in FIG. 1, to which only one channel C₁ is connected, may be the target device. In this case, the electric power measurement device 100 can obtain the input electric power (charging electric power) or the output electric power (discharging electric power) of the battery 10 on the basis of the sign of the measurement signal with respect to the set direction indicated by the reference information.

Alternatively, the electric motor, such as the power generation motor 20, the driving motor 30, and so forth, may be the target device. In this case, the electric power measurement device 100 can measure efficiency of the electric motor, in other words, efficiency of mechanical energy on the basis of the sign of the measurement signal with respect to the set direction of each phase indicated by the reference information.

In addition, in this embodiment, an example in which the transmission state of the PCU 40 that is the target device capable of transmitting the electric power in dual directions has been described; however, the present invention is not limited thereto. For example, the operational advantages provided by the electric power measurement device 100 of this embodiment can also be afforded for the target device, to which the plurality of channels can be connected, and in which the number of the paths of the electric power is increased/decreased in accordance with the operation mode of the target device although the transmission direction of the electric power transmitted through the channels.

In addition, in this embodiment, the PCU 40 connected to the three channels C₁ to C₃ are set as the target device; however, the target device may be connected to two channels or may be connected to four or more channels.

The present application claims a priority based on Japanese Patent Application 2021-084021 filed with the Japan Patent Office on May 18, 2021, the entire content of which is incorporated into this specification by reference.

### REFERENCE SIGNS LIST

1 electric power transmission system

10 battery

20 power generation motor

30 driving motor

40 PCU (target device)

100 electric power measurement device

110 memory unit (reference retaining circuit)

120 display unit (display equipment, notifying equipment)

130 operating unit

140 communication unit

150 measurement unit (electric power signal acquisition circuit)

160 processing unit (processor)

161 input calculation unit (second adder)

162 output calculation unit (first adder)

163 transmission index computation unit (calculator)

S1, S2, S3 to S10 (reference retaining step, electric power signal acquisition step, computing step)

What is claimed is:

1. A measurement device configured to measure a state of a target device, the target device being capable of switching at least one transmission direction of a channel among transmission directions of electric power transmitted through a plurality of channels, the measurement device comprising:
a reference retaining circuit configured to retain information indicating whether a reference transmission direction of the electric power transmitted through each of the channels is an input direction in which the electric power is input to the target device or an output direction in which the electric power is output from the target device;
an electric power signal acquisition circuit configured to acquire a signal indicating a direction and intensity of the electric power transmitted through each of the channels; and
a processor configured to compute at least one of input electric power and output electric power for the target device based on the sign indicating the direction of the signal with respect to the reference transmission direction of the electric power of each of the channels indicated by the information.

2. The measurement device according to claim 1, wherein
the processor comprises:
a first adder configured to obtain sum of an absolute value of the electric power of a channel in which the signal is positive among the channels in which the reference transmission direction of the electric power is the output direction and an absolute value of the electric power of a channel in which the signal is negative among the channels in which the reference transmission direction of the electric power is the input direction;
a second adder configured to obtain sum of an absolute value of the electric power of a channel in which the signal is positive among the channels in which the reference transmission direction of the electric power is the input direction and an absolute value of the electric power of a channel in which the signal is negative among the channels in which the reference transmission direction of the electric power is the output direction; and
a calculator configured to compute an index indicating the transmission state of the target device based on the sum obtained by the second adder and the sum obtained by the first adder.

3. The measurement device according to claim 2, wherein
the calculator is configured to calculate an electric power efficiency of the target device by dividing the sum obtained by the first adder by the sum obtained by the second adder.

4. The measurement device according to claim 2, wherein
the calculator is configured to calculate an electric power loss of the target device by subtracting the sum obtained by the first adder from the sum obtained by the second adder.

5. The measurement device according to claim 2, further comprising:
a plurality of sensors configured to detect an intensity of the electric power transmitted through the channels; and
a notifying equipment configured to notify the reference transmission direction indicated by the information for each of the channels.

6. The measurement device according to claim 2, further comprising:
a display equipment configured to display an image showing the reference transmission direction indicated by the information for each of the channels, wherein
the display equipment is configured to change the transmission direction shown in the image in accordance with change in the sign of the signal with respect to the reference transmission direction indicated by the information for each of the channels.

7. A measurement method for measuring a state of a target device, the target device being capable of switching at least one transmission direction of a channel among transmission directions of electric power transmitted through a plurality of channels, the measurement device comprising:
a reference retaining step of retaining information indicating whether a reference transmission direction of the electric power transmitted through each of the channels is an input direction in which the electric power is input to the target device or an output direction in which the electric power is output from the target device;
a electric power signal acquisition step of acquiring a signal indicating a direction and intensity of the electric power transmitted through each of the channels; and
a computing step of computing at least one of input electric power and output electric power for the target device based on the sign indicating the direction of the signal with respect to the reference transmission direction of the electric power of each of the channels indicated by the information.

8. A non-transitory computer-readable storage medium in which a program is recorded, the program causing a computer to execute following steps, the computer being configured to measure a state of target device, the target device being capable of switching at least one transmission direction of a channel among transmission directions of electric power transmitted through a plurality of channels, the steps being:
a reference retaining step of retaining information indicating whether a reference transmission direction of the electric power transmitted through each of the channels is an input direction in which the electric power is input to the target device or an output direction in which the electric power is output from the target device;
a electric power signal acquisition step of acquiring a signal indicating a direction and intensity of the electric power transmitted through each of the channels; and
a computing step of computing at least one of input electric power and output electric power for the target device based on the sign indicating the direction of the signal with respect to the reference transmission direction of the electric power of each of the channels indicated by the information.
